(19) United States
(12) Patent Application Publication
(10) Pub. No.: US 2025/0343197 A1
(43) Pub. Date: Nov. 6, 2025

(54) SEMICONDUCTOR PACKAGE AND METHODS

(71) Applicant: Taiwan Semiconductor Manufacturing Co., Ltd., Hsinchu (TW)

(72) Inventors: Chao-Wei Chiu, Hsinchu (TW); Hsiu-Jen Lin, Zhubei City (TW); Hsuan-Ting Kuo, Taichung City (TW); Ching-Hua Hsieh, Hsinchu (TW)

(21) Appl. No.: 19/271,021

(22) Filed: Jul. 16, 2025

Related U.S. Application Data
(63) Continuation of application No. 18/442,758, filed on Feb. 15, 2024.
(60) Provisional application No. 63/595,515, filed on Nov. 2, 2023.

(51) Int. Cl. H01L 23/00; H01L 21/52; H01L 23/053; H01L 23/28

(52) U.S. Cl. CPC H01L 24/32; H01L 21/52; H01L 23/053; H01L 23/28; H01L 24/29; H01L 2224/29019; H01L 2224/29109; H01L 2224/29111; H01L 2224/29144; H01L 2224/29147; H01L 2224/32245

(57) ABSTRACT

A semiconductor package and the method of forming the same are provided. The semiconductor package may include a substrate, a semiconductor package component having a semiconductor die bonded to the substrate, a lid attached to the substrate, and a first composite metal feature between the semiconductor package component and the lid. The first composite metal feature may include a first metal feature having a first material and a second metal feature having a second material. The first material may be an intermetallic compound. The second material may be different from the first material.

### PRIORITY CLAIM AND CROSS-REFERENCE

This application is a continuation of U.S. patent application Ser. No. 18/442,758, filed on Feb. 15, 2024, which claims the benefit of the following provisionally filed U.S. Patent Application No. 63/595,515, filed on Nov. 2, 2023, and entitled “Semiconductor Package with Thermal Conductive Structure,” each application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4A, 4B, 5, 6, 7A, 7B, 7C, 7D, 8A, 8B, 9A, 9B, and 9C illustrate the views of manufacturing steps in the formation of a semiconductor package in accordance with some embodiments.

FIGS. 10A, 10B, 10C, 10D, 10E, 10F, 11, 12A, 12B, and 12C illustrate the views of manufacturing steps in the formation of a semiconductor package in accordance with some alternative embodiments.

FIGS. 13A, 13B, and 14 illustrate the views of manufacturing steps in the formation of a semiconductor package in accordance with some alternative embodiments.

FIGS. 15A, 15B, and 16 illustrate the views of manufacturing steps in the formation of a semiconductor package in accordance with some alternative embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various semiconductor packages, each of which comprises semiconductor dies, a lid, and a composite metal feature comprising intermetallic compound(s) between the semiconductor dies and the lid, and the method of forming the same are provided. In accordance with some embodiments, the composite metal feature comprising intermetallic compound(s) may be generated by a reaction between metal features and a melted thermal interface material (TIM) layer over the semiconductor dies that at least partially converts the material of the TIM layer to the intermetallic compound(s). As a result, the risk of forming voids between the semiconductor dies and the lid during a subsequent reflow process may be lowered, which may improve the heat transfer efficiency from the semiconductor dies to the lid during the operation of the various semiconductor packages. Therefore, the performance and reliability of the various semiconductor packages may be improved.

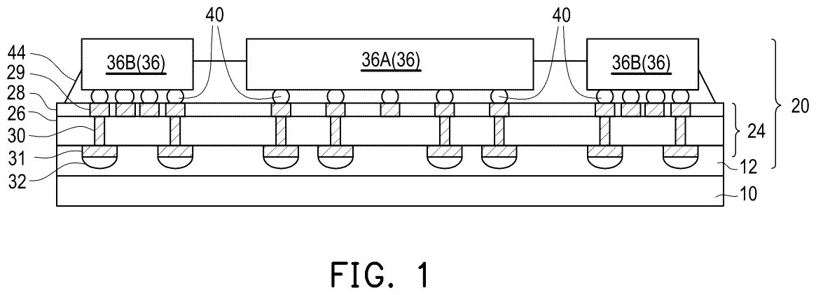

FIGS. 1, 2, 3, 4A, 4B, 5, 6, 7A, 7B, 7C, 7D, 8A, 8B, and 9A illustrate the views of manufacturing steps in the formation of a semiconductor package 100 in accordance with some embodiments. Referring to FIG. 1, a semiconductor package structure 20 is attached to a carrier 10 by a release film 12. The semiconductor package structure 20 may be a semiconductor wafer, which may comprise interposers, semiconductor dies, semiconductor die stacks, semiconductor packages, and/or the like. The semiconductor package structure 20 may comprise semiconductor package component 24 and semiconductor package components 36.

The semiconductor package component 24 may comprise a substrate 26, one or more dielectric layers 28 on a first side of the substrate 26, conductive features 29 in the dielectric layers 28, and conductive features 31 on a second side of the substrate 26. The conductive features 29 may comprise conductive lines and conductive vias. Through-substrate vias 30 may extend through the substrate 26 and may interconnect the conductive features 29 to the conductive features 31. Electrical connectors 32 may be on the conductive features 31 and may be used to bond to an external device in a subsequent step. The electrical connectors 32 may comprise solder regions. The semiconductor package component 24 may be referred to as an interposer wafer.

The semiconductor package components 36 may be physically and electrically connected (e.g., bonded) to the semiconductor package component 24. Each of the semiconductor package components 36 may be a semiconductor die, a semiconductor package with a semiconductor die(s), a System-on-Chip (SoC) die including a plurality of integrated circuits (or semiconductor dies) integrated as a system, or the like. The semiconductor package components 36 may be or may comprise logic dies, memory dies, input-output dies, Integrated Passive Devices (IPDs), the like, or combinations thereof. For example, the logic device dies may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies may be Static Random-Access Memory (SRAM) dies, Dynamic Random-Access Memory (DRAM) dies, or the like.

In some embodiments, the semiconductor package components 36 comprise semiconductor package components 36A and semiconductor package components 36B. The semiconductor package components 36A may be logic dies. The semiconductor package components 36B may be High-Performance Memory (HBM) die stacks. Each HBM die stack may include memory dies stacked on top of one another, and an encapsulant, such as a molding compound, encapsulating the memory dies. In some embodiments, the semiconductor package components 36 may generate heat during the operation of the subsequently formed semiconductor package 100. FIG. 1 illustrates one semiconductor package component 36A and two semiconductor package components 36B bonded to the semiconductor package component 24 as an example. Other quantities of the semiconductor package component 36A and the semiconductor package components 36B may be bonded the semiconductor package component 24.

Still referring to FIG. 1, semiconductor package components 36 may be physically and electrically connected (e.g., bonded) to the semiconductor package component 24 by electrical connectors 40, which may be in contact with the conductive features 29. The electrical connectors 40 may comprise solder regions. Underfill 44 may be dispensed between the semiconductor package components 36 and the semiconductor package component 24. The underfill 44 may be formed of a molding compound, epoxy, or the like.

The semiconductor package structure 20 may be attached to a carrier 10 by a release film 12. The carrier 10 may be a glass carrier, a polymer carrier, or the like. The release film 12 may be formed of a Light-To-Heat-Conversion (LTHC) material, which may be capable of being decomposed when exposed to a light beam, such as a laser beam. The conductive features 31 and the electrical connectors 32 may be embedded in the release film 12 and are spaced apart from the carrier 10.

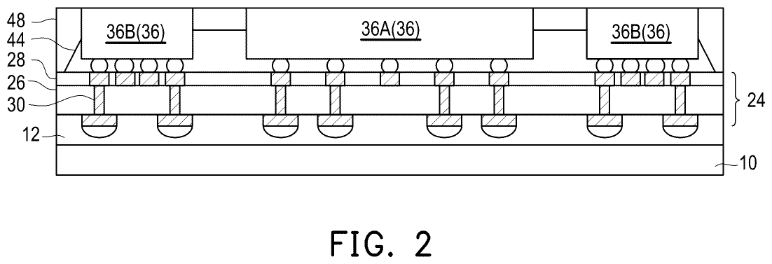

In FIG. 2, an encapsulant 48 is applied over the semiconductor package component 24 to encapsulate semiconductor package components 36 and the underfill 44. The encapsulant 48 may be a molding compound, epoxy, or the like. The encapsulant 48 may be applied by compression molding, transfer molding, or the like, and may be applied over the semiconductor package component 24 such that the semiconductor package components 36 are buried or covered. The encapsulant 48 may be applied in gap regions between the semiconductor package components 36. The encapsulant 48 may be applied in liquid or semi-liquid form and then subsequently cured. Then the encapsulant 48 may be thinned to expose the semiconductor package components 36. The thinning process may be a grinding process, a chemical-mechanical polish (CMP), an etch-back, combinations thereof, or the like. After the thinning process, the top surfaces of the semiconductor package components 36 and the encapsulant 48 are substantially coplanar (within process variations). The thinning is performed until a desired amount of the semiconductor package components 36 and the encapsulant 48 has been removed.

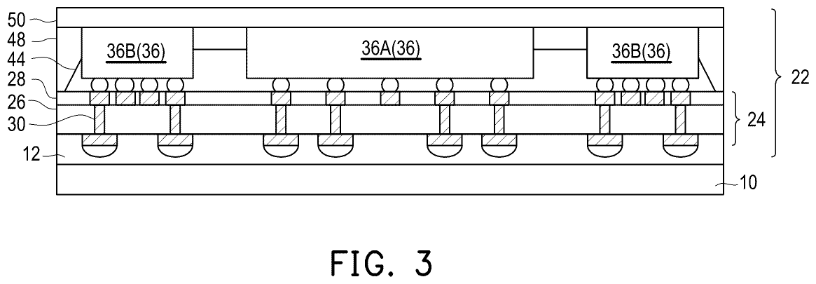

In FIG. 3, a metal layer 50 is formed on the top surfaces of the semiconductor package components 36 and the encapsulant 48. The metal layer 50 may be formed through a deposition process, such as Physical Vapor Deposition (PVD) or the like. The metal layer 50 may be a single layer or a composite layer comprising multiple sub-layers formed of different materials. The single layer or each of the multiple sub-layers of the metal layer 50 may be formed of a homogenous metallic material, a metal alloy, or the like. In some embodiments, the metal layer 50 is a single layer and comprises copper. In some embodiments, the metal layer 50 is a composite layer that comprises a plurality of sub layers. For example, the metal layer 50 may include an aluminum layer as a bottom sub-layer, a titanium layer as a middle sub-layer, and a copper layer as a top sub-layer. The metal layer 50 may be in contact with the silicon substrates in semiconductor package components 36 and may dissipate the heat generated by semiconductor package components 36 during the operation of the subsequently formed semiconductor package 100. The semiconductor package structure 20, the encapsulant 48, and the metal layer 50 may be collectively referred to as the semiconductor package structure 22.

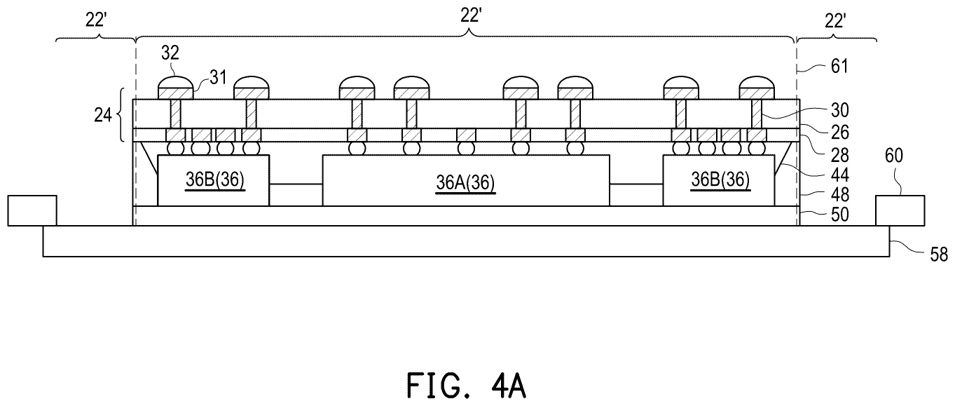

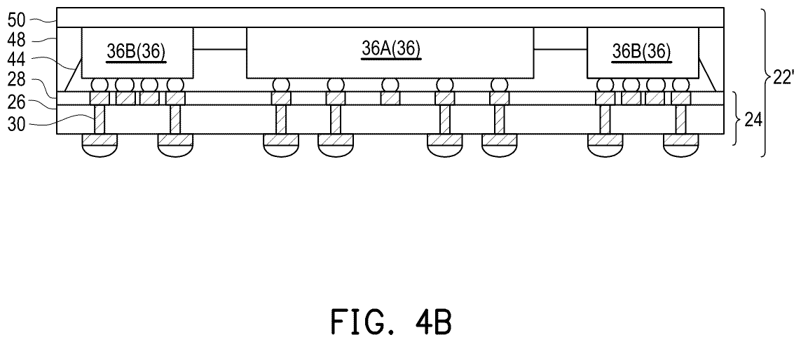

In FIG. 4A, the semiconductor package structure 22 is removed from the carrier 10 and singulated into individual semiconductor package components 22′. The semiconductor package structure 22 may be removed from the carrier 10 by projecting a light beam, such as a laser beam, on the release film 12, which may cause the release film 12 to de-compose. The semiconductor package structure 22 may be then released from the carrier 10, and the conductive features 31 and the electrical connectors 32 may be exposed. The semiconductor package structure 22 may be then placed on a tape 58, which is fixed on a frame 60. The semiconductor package structure 22 may be singulated along scribe lines 61 into individual semiconductor package components 22′. The singulation process may be performed by sawing, dicing, or the like. Then the semiconductor package components 22′ are removed from the tape 58. FIG. 4B illustrates one semiconductor package component 22′.

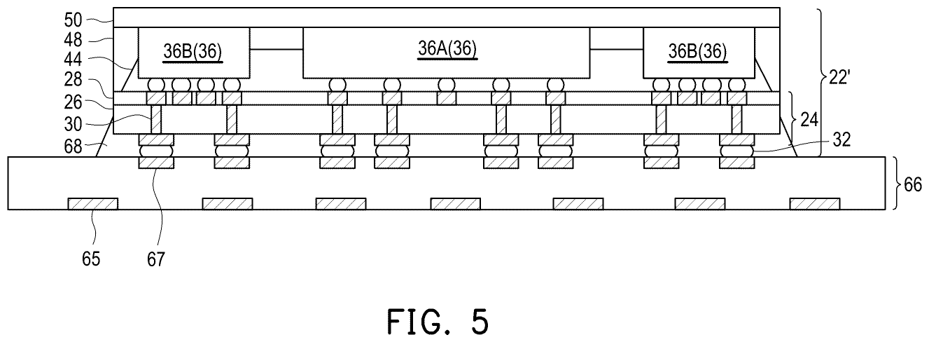

In FIG. 5, the semiconductor package component 22′ is physically and electrically connected (e.g., bonded) to a package substrate 66 and an underfill 68 is dispensed in the gap between the semiconductor package component 22′ and the package substrate 66. The semiconductor package component 22′ may be bonded to the package substrate 66 by the electrical connectors 32. The package substrate 66 may comprise conductive contacts 65 on a first side (e.g., bottom side) and conductive contacts 67 on a second side (e.g., top side). The conductive contacts 65 may be electrically connected to the conductive contacts 67 by conductive features inside the package substrate 66 (not shown). The electrical connectors 32 may be in contact with the conductive contacts 67. Electrical connectors may be formed on the conductive contacts 65 in a subsequent step. The package substrate 66 may further comprise active or inactive devices (not shown). The underfill 68 may be formed of a molding compound, epoxy, or the like. The underfill 68 may be formed by a capillary flow process after the semiconductor package component 22′ is connected to the package substrate 66, or may be formed by a suitable deposition method before the semiconductor package component 22′ is connected to the package substrate 66. The underfill 68 may be applied in liquid or semi-liquid form and then subsequently cured.

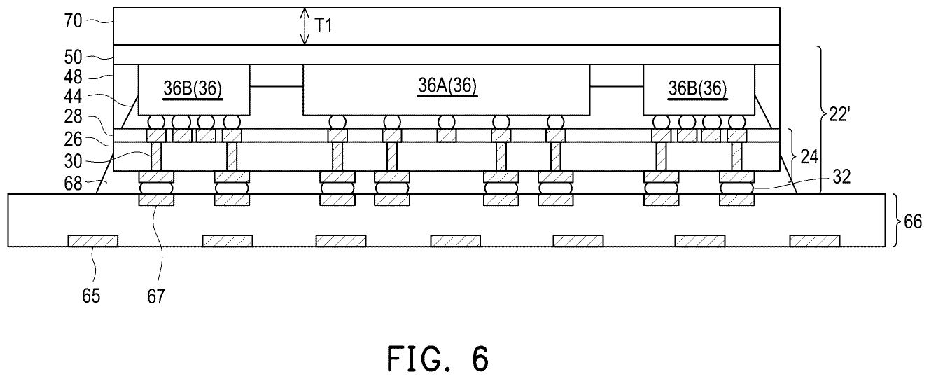

In FIG. 6, a TIM layer 70 is formed on the metal layer 50. The TIM layer 70 may comprise a material with high thermal conductivity, such as metal, metal alloy, or the like. In some embodiments, the TIM layer 70 comprises indium (In), tin (Sn), indium-silver (In—Ag) alloy, tin-bismuth (Sn—Bi) alloy, gallium (Ga), or the like. The TIM layer 70 may be formed by plating, such as electroplating or electroless plating, or the like. The metal layer 50 may be used as a seed layer during the plating process. In some embodiments, the TIM layer 70 has a thickness T1 in a range between about 50 μm and about 100 μm.

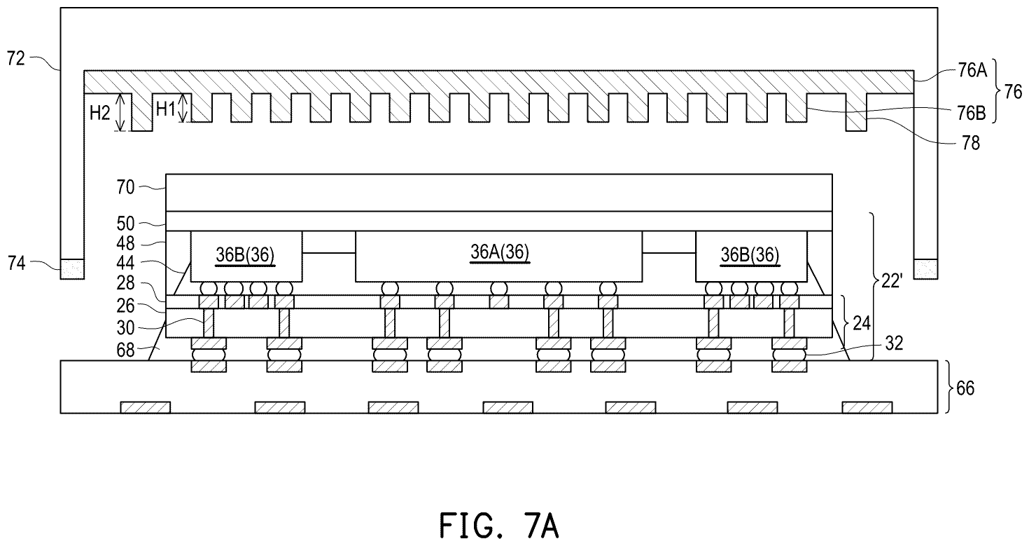

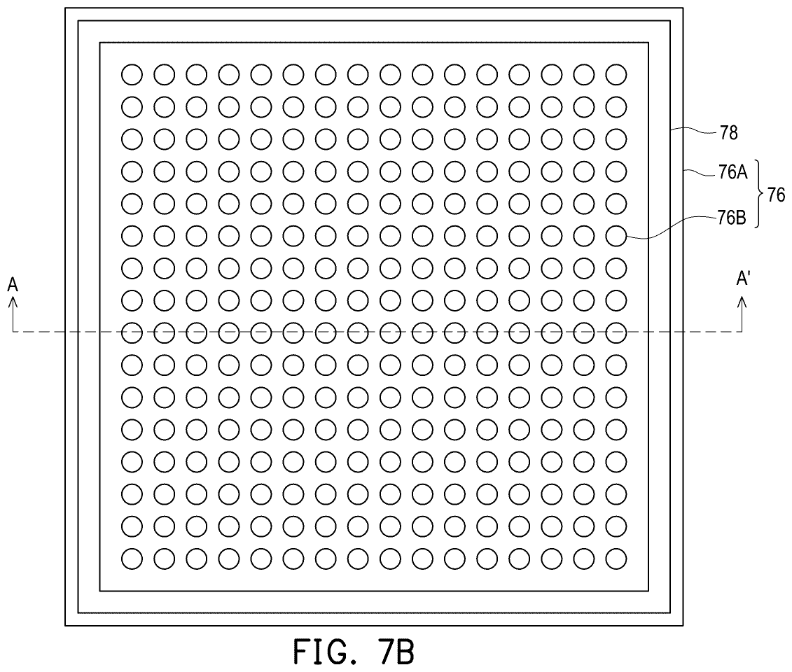

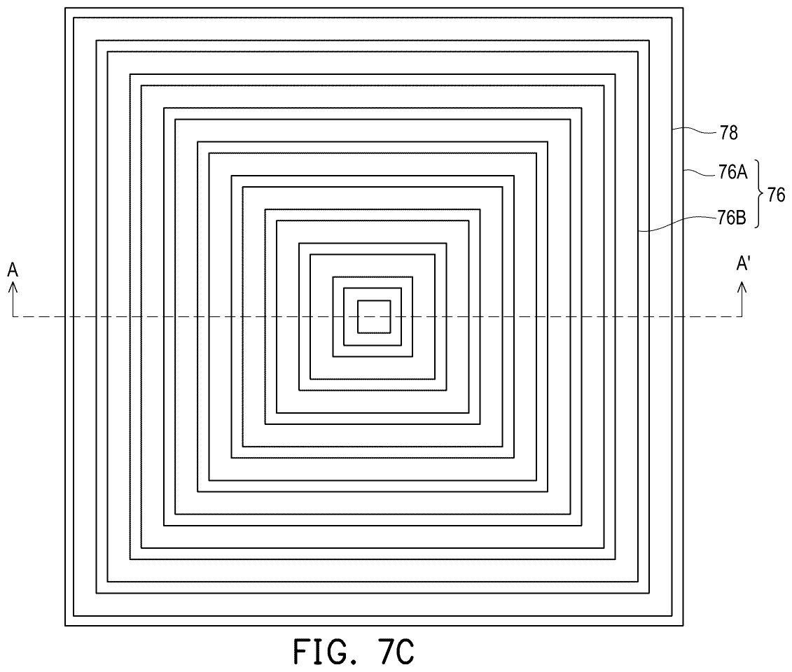

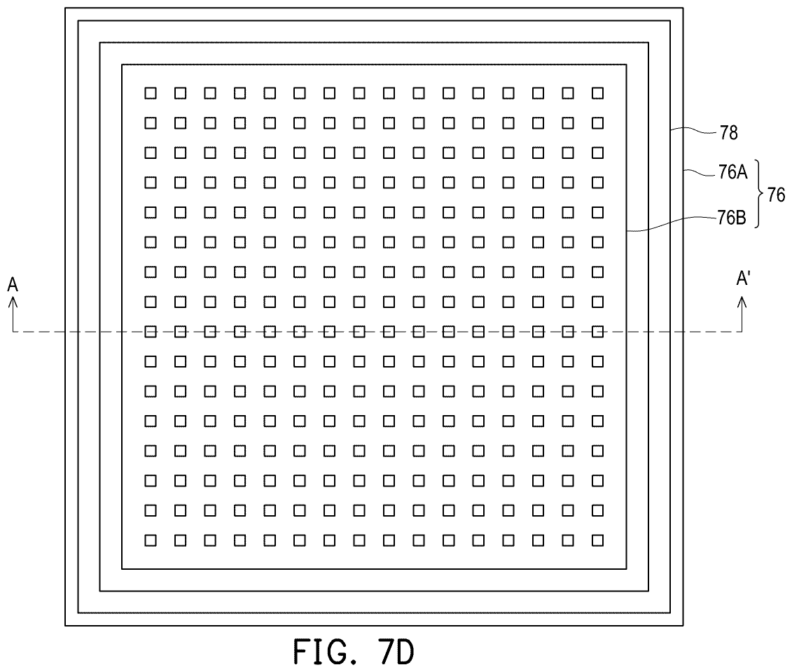

In FIG. 7A, a lid 72 with a metal feature 76 is placed over the structure shown in FIG. 6. The cross-sectional view of the metal feature 76 in FIG. 7A may be obtained along reference cross-section A-A′ in a bottom-up view of the metal feature 76 in FIG. 7B, wherein like reference numerals refer to like features formed by like processes. The lid 72 may have a top portion and a sidewall portion. The sidewall portion of the lid 72 may encircle the semiconductor package component 22′ in a top-down view. The metal feature 76 may be on a bottom surface of the top portion of the lid 72. Adhesive 74, such as an epoxy, may be on a bottom surface of the sidewall portion of the lid 72. The lid 72 may be attached to the package substrate 66 by the adhesive 74 in a subsequent step. The metal feature 76 may comprise a base layer 76A on the bottom surface of the top portion of the lid 72 and protrusions 76B on the base layer 76A. In some embodiments, a ratio of a volume of the protrusions 76B to a volume of the TIM layer 70 is in a range between about 0.2 and about 0.7, such as about 0.55, which may lead to a complete conversion of the TIM layer 70 to a different metal feature in a subsequent step as described in greater details below. In some embodiments, the protrusions 76B have a same height H1 in a range between about 50 μm and about 100 μm. In the embodiments shown in FIG. 7B, the protrusions 76B are an array of pillars. The quantity, shape, and arrangement of the protrusions 76B shown in FIGS. 7A and 7B are provided as an example. Other quantities, shapes, and arrangements of the protrusions 76B are contemplated.

The lid 72 may be formed of copper, stainless steel, or the like. The metal feature 76 may comprise a material with high thermal conductivity and a high melting point M1, such as copper (Cu), gold (Au), or the like. The material of the metal feature 76 may also be ones that are capable of reacting with the material of the TIM layer 70 to form intermetallic compounds as described in greater details below. A thermal conductivity of the metal feature 76 may be larger than a thermal conductivity of the TIM layer 70. The metal feature 76 may be formed by plating, such as electroplating or electroless plating, or the like. A barrier 78 may be formed on the base layer 76A and encircle the protrusions 76B in the bottom-up view (see FIGS. 7B-7D). The barrier 78 may confine the TIM layer 70 when protrusions 76B insert into the melted TIM layer 70 in a subsequent step as described in greater details later. In some embodiments, the barrier 78 is formed of a same material and by a same process as the metal feature 76. In some embodiments, the barrier 78 has a height H2 in a range between about 55 um and about 120 um. The height H2 of the barrier 78 may be larger than the height H1 of the protrusions 76B.

FIGS. 7C and 7D show bottom-up views of the metal feature 76, similar to the one shown in FIG. 7B, in accordance with some embodiments. The cross-sectional view of the metal feature 76 in FIG. 7A may be obtained along the reference cross-section A-A′ in the bottom-up views of the metal feature 76 in FIGS. 7C and 7D, wherein like reference numerals refer to like features formed by like processes. In the embodiments shown in FIG. 7C, the protrusions 76B are concentric rings. In the embodiments shown in FIG. 7D, the protrusions 76B are interconnected strips (e.g., a grid).

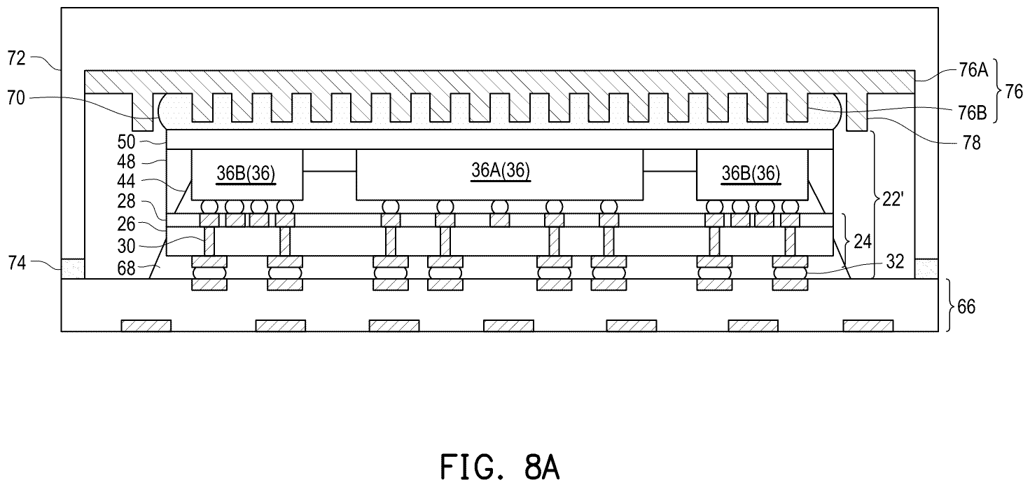

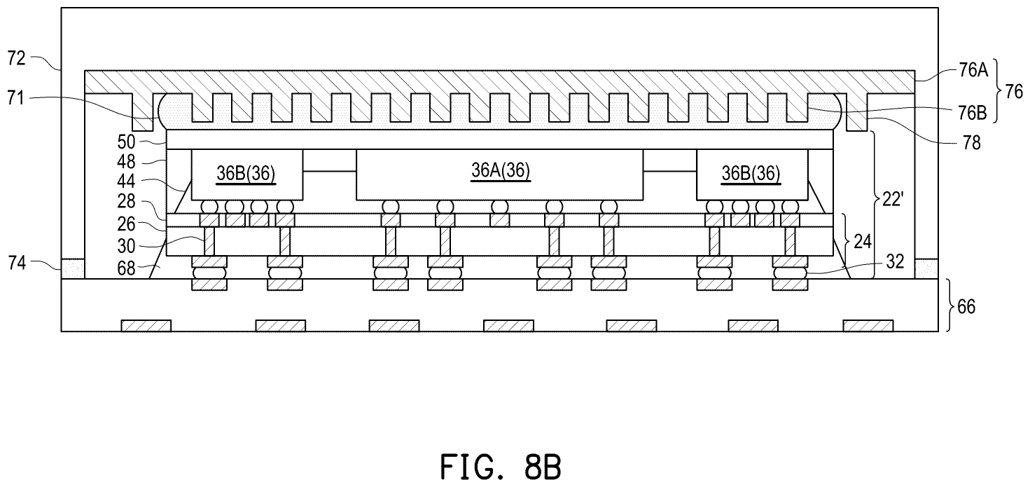

FIGS. 8A and 8B illustrate different steps of an attachment process between the lid 72 and the package substrate 66 as well as a conversion process between the metal feature 76 and the TIM layer 70. As a result of the conversion process, the TIM layer 70 may be converted to a metal feature comprising intermetallic compound(s). The metal feature comprising intermetallic compound(s) may have a higher melting point than the TIM layer 70, which may lower the risk of forming voids between the semiconductor package components 22′ and the lid 72 during a subsequent step as described in greater details below.

In FIG. 8A, the lid 72 is lowered towards the structure shown in FIG. 6 as the said

structure may be heated at a temperature C1 in a range between about 150° C. and about 180° C., such as about 156° C. The temperature C1 may be larger than a melting point M2 of the TIM layer 70. The TIM layer 70 may melt at the temperature C1 while the protrusions 76B of the metal feature 76 insert into the TIM layer 70. The melted TIM layer 70 may spread laterally when the protrusions 76B insert into the TIM layer 70. In some embodiments, the melted TIM layer 70 has convex sidewalls that protrude towards the barrier 78. In some embodiments, the melted TIM layer 70 contacts the barrier 78 (not shown). Once the metal feature 76 contact the melted TIM layer 70, the material of the metal feature 76 may start to react with the material of the TIM layer 70 to generate corresponding intermetallic compound(s). The adhesive 74 may be cured at the temperature C1 and attach the sidewall portion of the lid 72 to the package substrate 66.

In FIG. 8B, the structure shown in FIG. 8A continues being heated at the temperature C1 until the reaction between the metal feature 76 and the TIM layer 70 is completed. As a result, the TIM layer 70 is converted to a metal feature 71 comprising intermetallic compound(s) and the metal feature 71 may be bonded to the metal feature 76. The metal feature 71 and the metal feature 76 may contact each other and have an interdigitating pattern. The metal feature 71 and the metal feature 76 may be collectively referred to as a composite metal feature. In some embodiments, the metal feature 71 has convex sidewalls that protrude towards the barrier 78. In some embodiments, the sizes of the protrusions 76B may be reduced after the reaction between the metal feature 76 and the TIM layer 70. In some embodiments, after said reaction, a ratio of the volume of the protrusions 76B to a volume of the metal feature 71 is in a range between about 0.2 and about 0.3, such as about 0.25. In the embodiments shown in FIG. 8B, the protrusions 76B may be spaced apart from the metal layer 50 by the metal feature 71. In some embodiments, the TIM layer 70 is completely converted to intermetallic compound(s) free of particles of a homogenous metallic material. In some embodiments, the TIM layer 70 is partially converted to intermetallic compound(s) with particles of a homogenous metallic material embedded within.

The metal feature 71 comprising intermetallic compound(s) may have a melting point M3 greater than the melting point M2 of the TIM layer 70, which may lower the risk of forming voids between the semiconductor package components 22′ and the lid 72 during a subsequent step as described in greater details below. The melting point M1 of the metal feature 76 may be larger than the melting point M3 of the metal feature 71. In the embodiments, the melting point M3 of the metal feature 71 may be greater than about 217° C. In the embodiments where the TIM layer 70 comprises indium (In) and the metal feature 76 comprises copper (Cu), the metal feature 71 comprises intermetallic compound Cu₁₁In₉, which has a melting point at about 310° C. In the embodiments where the TIM layer 70 comprises indium (In) and the metal feature 76 comprises gold (Au), the metal feature 71 comprises intermetallic compound Au₂In₂, which has a melting point at about 496° C. In the embodiments where the TIM layer 70 comprises tin (Sn) and the metal feature 76 comprises copper (Cu), the metal feature 71 comprises intermetallic compounds Cu₆Sn₅ and Cu₃Sn, which have melting points at about 415° C. and about 676° C., respectively. In the embodiments where the TIM layer 70 comprises tin (Sn) and the metal feature 76 comprises gold (Au), the metal feature 71 comprises intermetallic compound Au₂Sn₄, which has a melting point at about 320° C. In the embodiments where the TIM layer 70 comprises gallium (Ga) and the metal feature 76 comprises copper (Cu), the metal feature 71 comprises intermetallic compound CuGa₂, which has a melting point at about 259° C. In the embodiments where the TIM layer 70 comprises gallium (Ga) and the metal feature 76 comprises gold (Au), the metal feature 71 comprises intermetallic compound AuGa₂, which has a melting point at about 454° C.

In the embodiments where the TIM layer 70 comprises indium-silver (In—Ag) alloy and the metal feature 76 comprises copper (Cu), the metal feature 71 comprises intermetallic compound CunIn, and silver (Ag) particles embedded in the intermetallic compound CunIng. In the embodiments where the TIM layer 70 comprises indium-silver (In—Ag) alloy and the metal feature 76 comprises gold (Au), the metal feature 71 comprises intermetallic compound Au₂In₂ and silver (Ag) particles embedded in the intermetallic compound Au₂In₂. In the embodiments where the TIM layer 70 comprises tin-bismuth (Sn—Bi) alloy and the metal feature 76 comprises copper (Cu), the metal feature 71 comprises intermetallic compounds Cu₆Sn₅ and Cu₃Sn and bismuth (Bi) particles embedded in the intermetallic compounds Cu₆Sn₅ and Cu₃Sn. In the embodiments where the TIM layer 70 comprises tin-bismuth (Sn—Bi) alloy and the metal feature 76 comprises gold (Au), the metal feature 71 comprises intermetallic compound Au₂Sn₄ and bismuth (Bi) particles embedded in the intermetallic compound Au₂Sn₄.

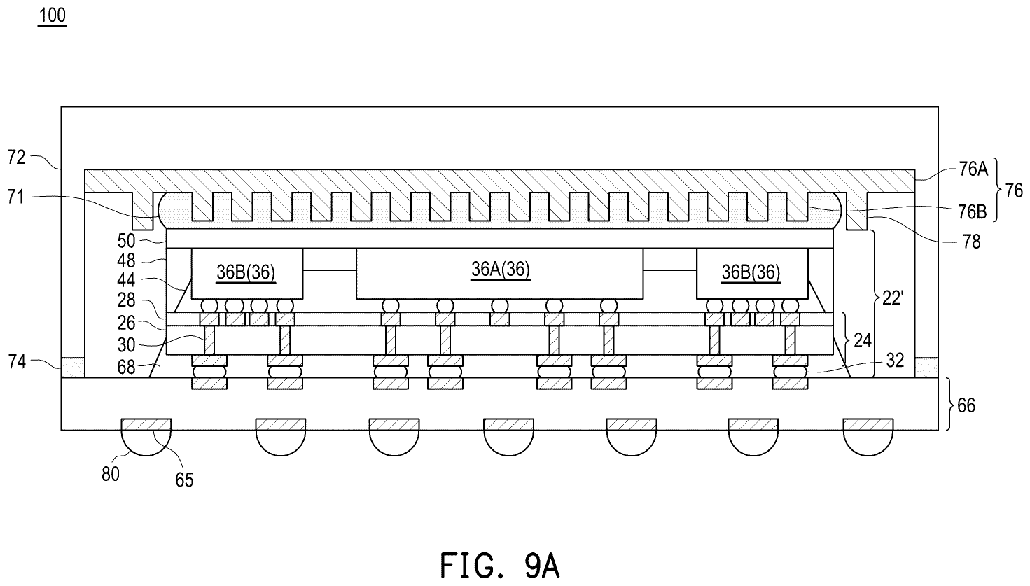

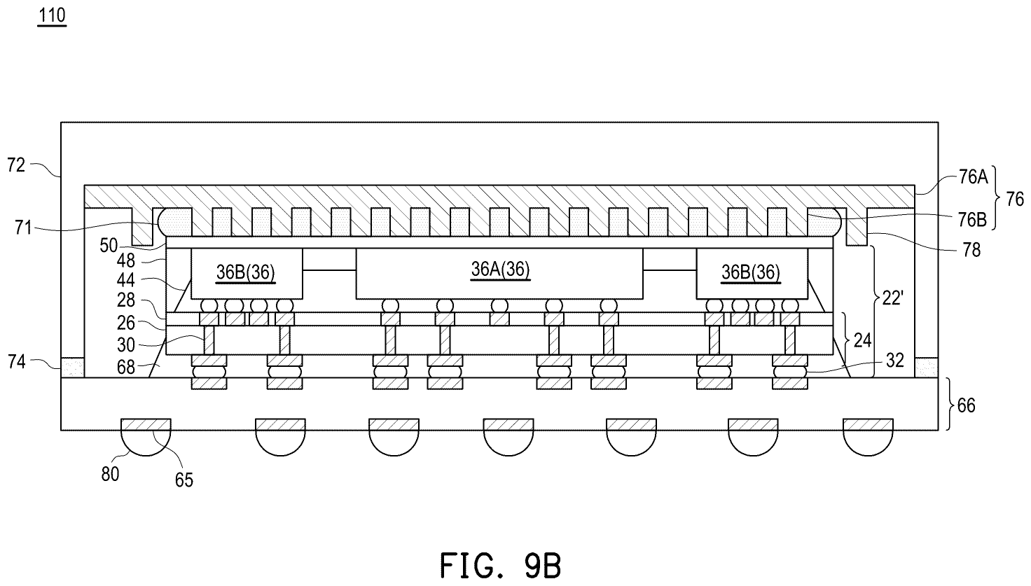

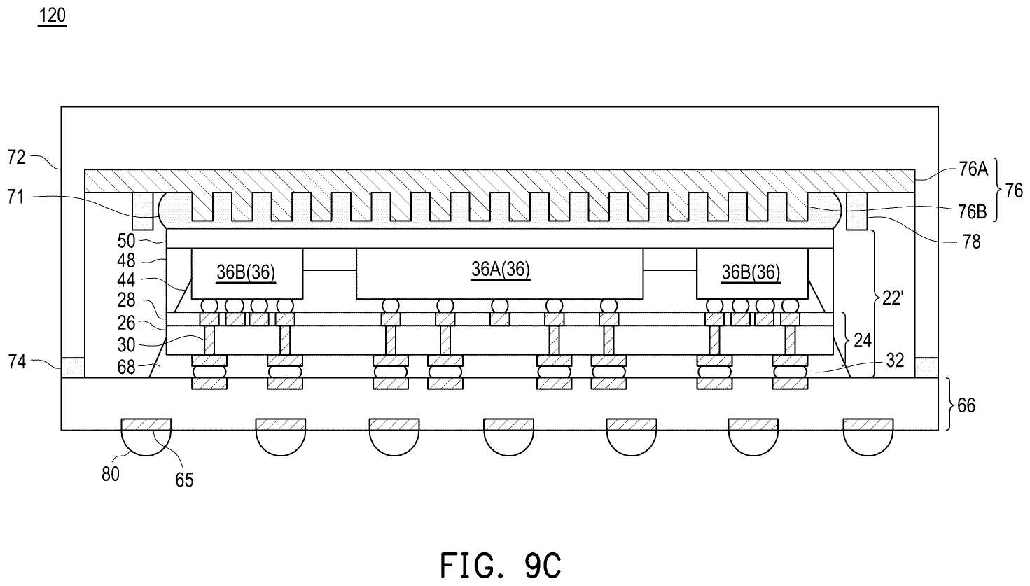

In FIG. 9A, conductive connectors 80 are formed on the conductive contacts 65 in the package substrate 66. The structure shown in FIG. 9A may be referred to as the semiconductor package 100. The conductive connectors 80 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 80 may be formed of a conductive material that is reflowable, such as solder, copper, aluminum, gold, nickel, silver, palladium, tin, the like, or a combination thereof. The conductive connectors 80 may be formed by initially forming a layer of solder on the conductive contacts 65 through evaporation, electroplating, printing, solder transfer, ball placement, or the like. Once a layer of solder has been formed on the conductive contacts 65, a reflow process may be performed in order to shape the material into desired bump shapes. The reflow process may be performed at a temperature C2 around 217° C. The temperature C2 may be larger than the melting point M2 of the TIM layer 70 and smaller than the melting point M3 of the metal feature 71. As a result, the metal feature 71 may stay intact (e.g., remain solid) during the reflow process of the conductive connectors 80 without melting or forming voids within. By converting the TIM layer 70 to the metal feature 71, the risk of forming voids between the semiconductor package components 22′ and the lid 72 during the reflow process of the conductive connectors 80 may be lowered, which may improve the heat transfer efficiency from the semiconductor package components 22′ to the lid 72 during the operation of the semiconductor package 100. The protrusions 76B may also improve the heat transfer efficiency from the semiconductor package components 22′ to the lid 72 during the operation of the semiconductor package 100. As a result, the performance and reliability of the semiconductor package 100 may be improved.

FIG. 9B shows a semiconductor package 110 similar to the semiconductor package 100 shown in FIG. 9A, in accordance to some embodiments, wherein like reference numerals refer to like features formed by like processes. In the semiconductor package 110, the protrusions 76B of the metal feature 76 extend through the metal feature 71 and are in contact with the metal layer 50. FIG. 9C shows a semiconductor package 120 similar to the semiconductor package 100 shown in FIG. 9A, in accordance to some embodiments, wherein like reference numerals refer to like features formed by like processes. In the semiconductor package 110, the barrier 78 may be formed of a different material from the metal feature 76, such as resin or the like. The barrier 78 may be formed on the base layer 76A of the metal feature 76 by painting a selected material followed by curing and may remain intact (e.g., remain solid) during the reflow process of the conductive connectors 80 at the temperature C2.

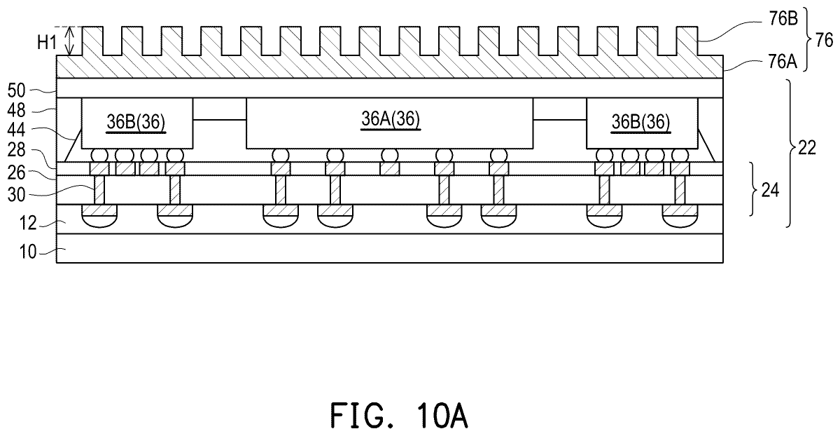

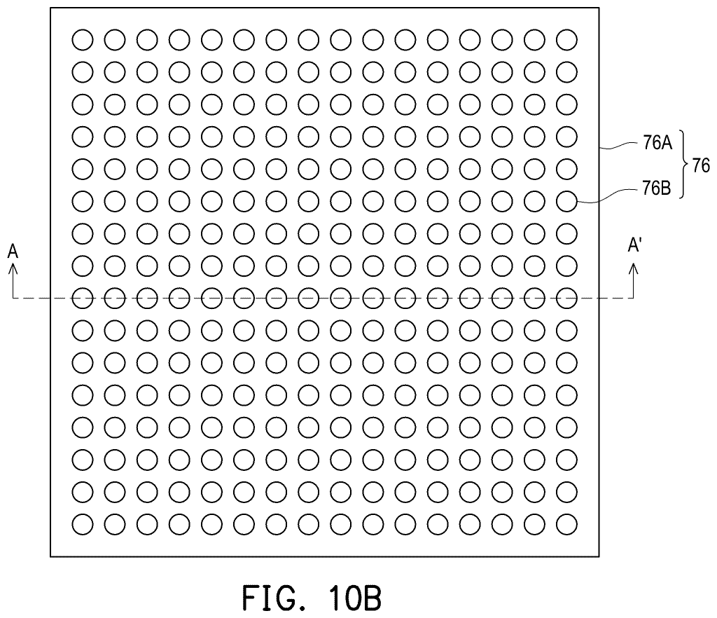

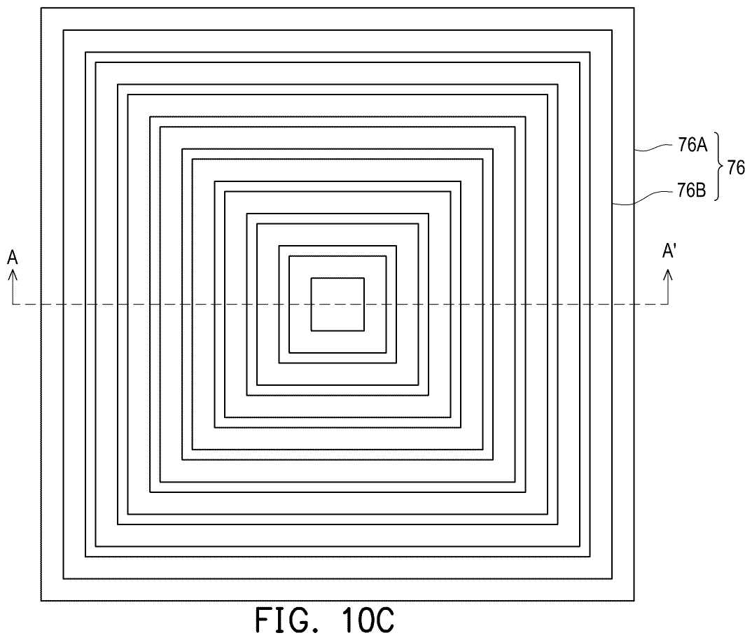

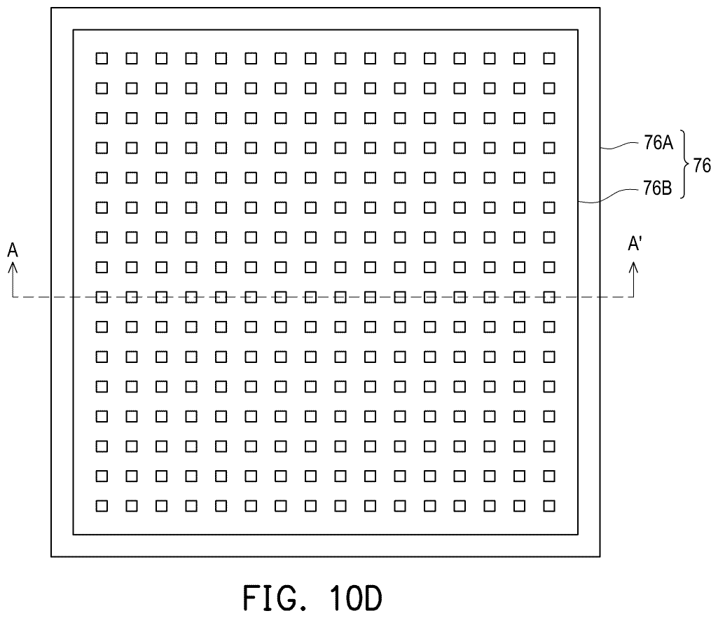

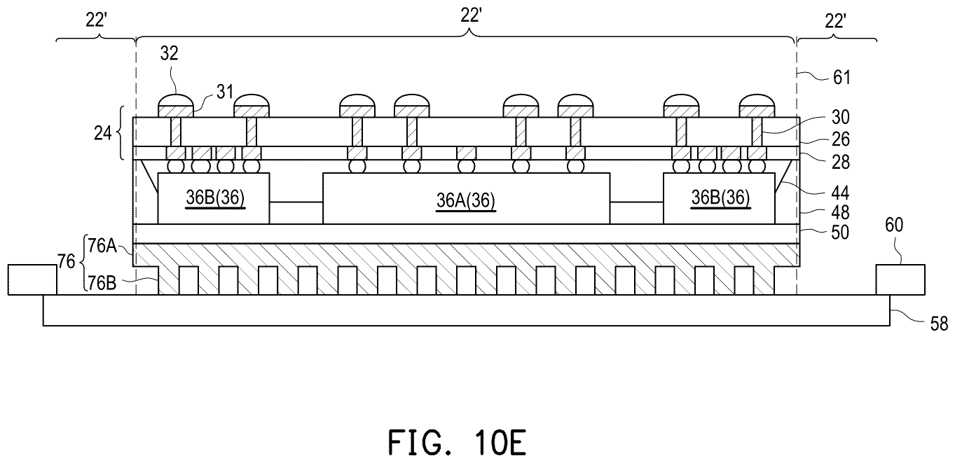

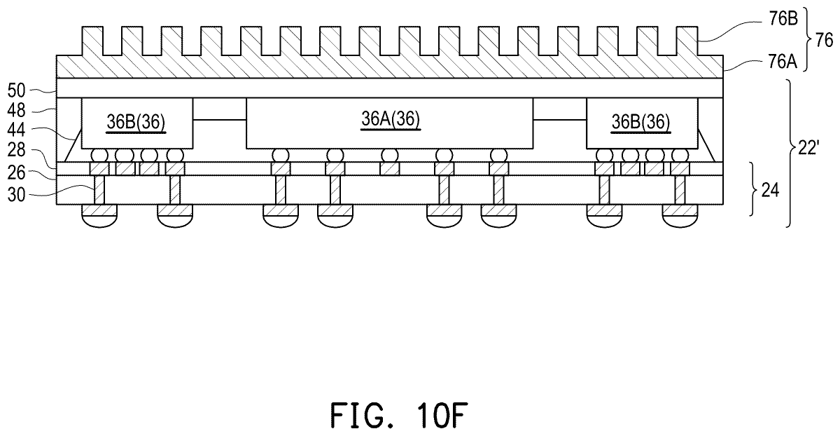

FIGS. 10A, 10B, 10C, 10D, 10E, 10F, 11, and 12A illustrate the views of manufacturing steps in the formation of a semiconductor package 130 in accordance with some embodiments. Referring to FIG. 10A, after performing the processes described with respect to FIGS. 1 through 3, the metal feature 76 are formed on the metal layer 50 of the semiconductor package structure 22. Within each region of the semiconductor package structure 22 that may be subsequently singulated into the semiconductor package component 22′, the metal feature 76 shown in FIG. 10A may have same or similar structure and may be formed of same or similar materials and methods as the metal feature 76 described above with respect to FIG. 7A. In some embodiments, the protrusions 76B have the same height H1 in a range between about 50 um and about 100 μm.

The cross-sectional view of the metal feature 76 in FIG. 10A may be obtained along the reference cross-section A-A′ in top-down views of the metal feature 76 in FIGS. 10B, 10C, and 10D, wherein like reference numerals refer to like features formed by like processes. In the embodiments shown in FIG. 10B, the protrusions 76B are an array of pillars. In the embodiments shown in FIG. 10C, the protrusions 76B are concentric rings. In the embodiments shown in FIG. 10D, the protrusions 76B are interconnected strips (e.g., a grid). The quantities, shapes, and arrangements of the protrusions 76B shown in FIGS. 10A, 10B, and 10C are provided as examples. Other quantities, shapes, and arrangements of the protrusions 76B are contemplated.

In FIG. 10E, the semiconductor package structure 22 with the metal feature 76 as shown in FIG. 10A is removed from the carrier 10 and singulated into individual semiconductor package components 22′ with the metal feature 76. The semiconductor package structure 22 may be removed from the carrier 10 by projecting a light beam, such as a laser beam, on the release film 12, which may cause the release film 12 to de-compose. The semiconductor package structure 22 may be then released from the carrier 10, and the conductive features 31 and the electrical connectors 32 may be exposed. The semiconductor package structure 22 with the metal feature 76 may be then placed on a tape 58, which is fixed on a frame 60. The semiconductor package structure 22 with the metal feature 76 may be singulated along scribe lines 61 into individual semiconductor package components 22′ with the metal feature 76. The singulation process may be performed by sawing, dicing, or the like. Then the semiconductor package components 22′ with the metal features 76 are removed from the tape 58. FIG. 10F illustrates one semiconductor package component 22′ with the metal feature 76.

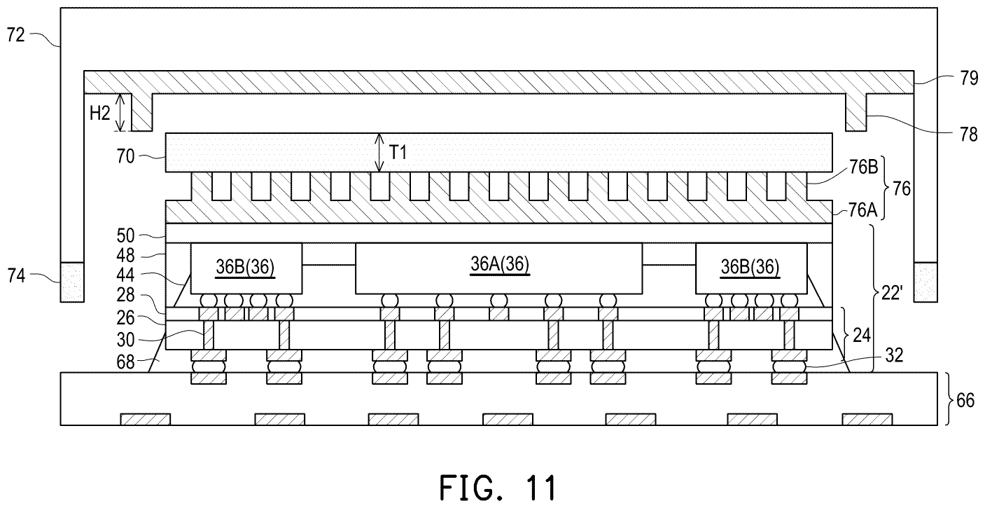

In FIG. 11, after performing the processes similar to the ones described with respect to FIG. 5, such as physically and electrically connecting (e.g., bonding) the semiconductor package component 22′ with the metal feature 76 to the package substrate 66 and dispensing the underfill 68 in the gap between the semiconductor package component 22′ and the package substrate 66, the TIM layer 70 is placed on the metal feature 76 and the lid 72 is placed over the TIM layer 70. The TIM layer 70 shown in FIG. 11 may be formed of same or similar materials as the TIM layer 70 described above with respect to FIG. 7A. A base layer 79 may be formed on the bottom surface of the top portion of the lid 72 and the barrier 78 may be formed on the base layer 79. The base layer 79 may be formed of copper (Cu) or the like and formed by plating or the like. In some embodiments, the barrier 78 is formed of a same material and by a same process as the base layer 79. In some embodiments, the TIM layer 70 has the thickness T1 in a range between about 50 μm and about 100 μm. In some embodiments, the ratio of the volume of the protrusions 76B to the volume of the TIM layer 70 is in a range between about 0.2 and about 0.7, such as about 0.55, which may lead to the complete conversion of the TIM layer 70 to the metal feature 71 in a subsequent step as described in greater details below. In some embodiments, the barrier 78 has the height H2 in a range between about 55 μm and about 120 μm. The height H2 may be larger than the height H1 of the protrusions 76B.

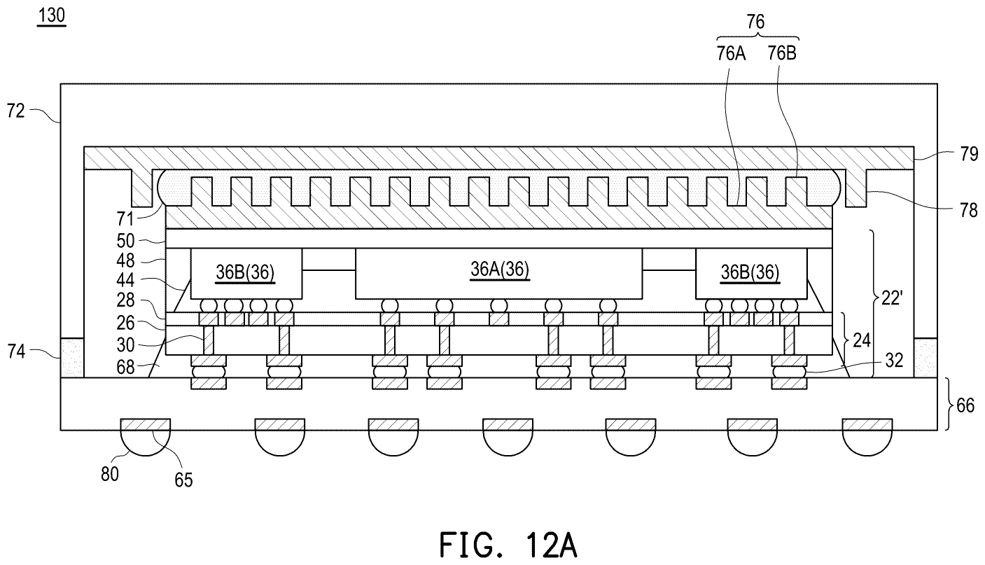

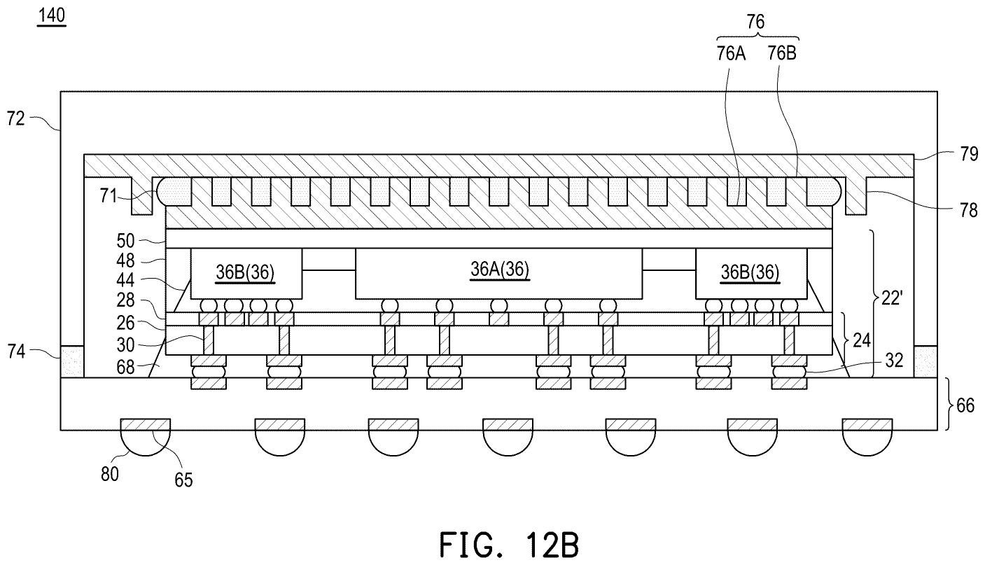

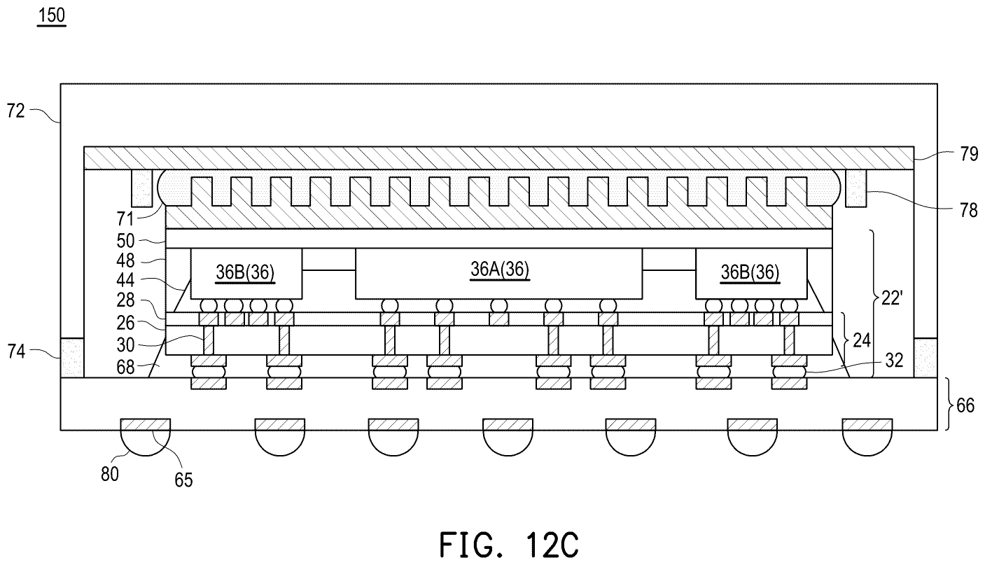

In FIG. 12A, after performing the processes similar to the ones described with respect to FIGS. 8A through 9A, such as attaching the lid 72 to the package substrate 66, inserting the protrusions 76B into the melted the TIM layer 70, converting the TIM layer 70 to the metal feature 71 comprising intermetallic compound(s), and forming the conductive connectors 80, the semiconductor package 130 is formed. The metal feature 71 and the metal feature 76 may contact each other and have an interdigitating pattern. The metal feature 71 and the metal feature 76 may be collectively referred to as a composite metal feature. The barrier 78 may encircle the protrusions 76B in the top-down view (not shown). In some embodiments, the sizes of the protrusions 76B may be reduced after the reaction between the metal feature 76 and the TIM layer 70. In some embodiments, after said reaction, a ratio of the volume of the protrusions 76B to the volume of the metal feature 71 is in a range between about 0.2 and about 0.3, such as about 0.25. In the embodiments shown in FIG. 12A, the protrusions 76B may be spaced apart from the base layer 79 by the metal feature 71. In some embodiments, the TIM layer 70 is completely converted to intermetallic compound(s) free of particles of a homogenous metallic material. In some embodiments, the TIM layer 70 is partially converted to intermetallic compound(s) with particles of a homogenous metallic material embedded within. The metal feature 71 shown in FIG. 12A may comprise same or similar intermetallic compound(s) described above with respect to FIG. 8B.

For similar reasons described above with respect to FIG. 9A, by converting the TIM layer 70 to the metal feature 71, the risk of forming voids between the semiconductor package components 22′ and the lid 72 during the reflow process of the conductive connectors 80 may be lowered, which may improve the heat transfer efficiency from the semiconductor package components 22′ to the lid 72 during the operation of the semiconductor package 130. The protrusions 76B may also improve the heat transfer efficiency from the semiconductor package components 22′ to the lid 72 during the operation of the semiconductor package 130. As a result, the performance and reliability of the semiconductor package 130 may be improved.

FIG. 12B shows a semiconductor package 140 similar to the semiconductor package 130 shown in FIG. 12A, in accordance to some embodiments, wherein like reference numerals refer to like features formed by like processes. In the semiconductor package 140, the protrusions 76B of the metal feature 76 extend through the metal feature 71 and are in contact with the base layer 79. FIG. 12C shows a semiconductor package 150 similar to the semiconductor package 130 shown in FIG. 12A, in accordance to some embodiments, wherein like reference numerals refer to like features formed by like processes. In the semiconductor package 150, the barrier 78 may be formed of a different material from the base layer 79, such as resin or the like. The barrier 78 may be formed on the base layer 79 by painting followed by curing and may remain intact (e.g., remain solid) during the reflow process of the conductive connectors 80 at the temperature C2.

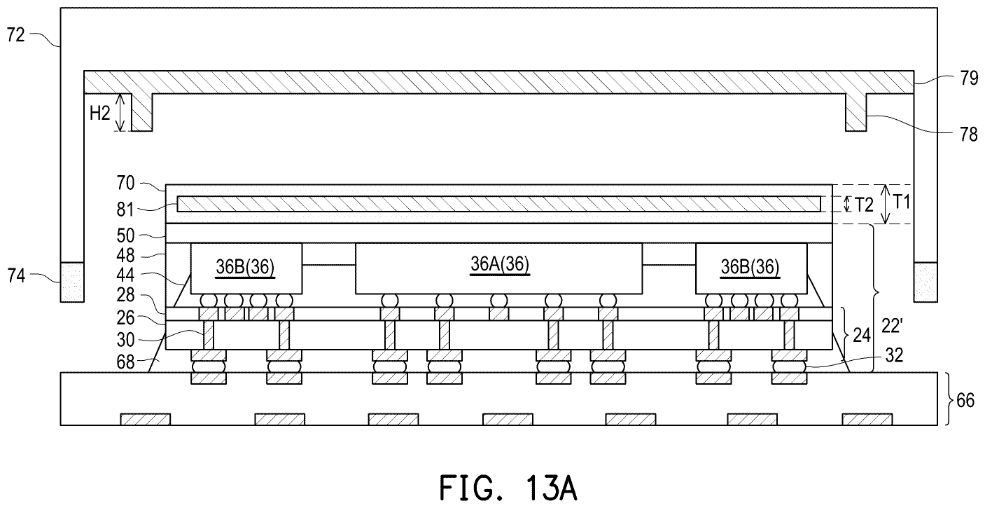

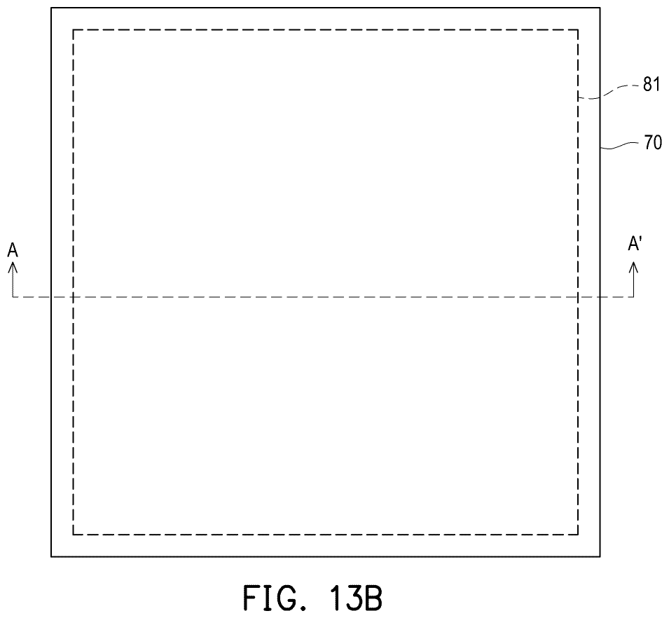

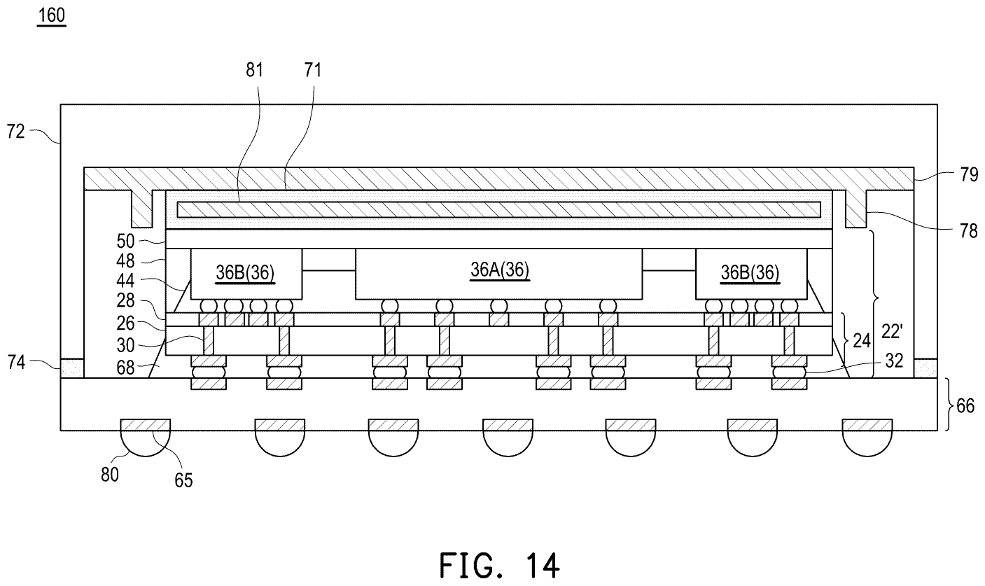

FIGS. 13A, 13B, and 14 illustrate the views of manufacturing steps in the formation of a semiconductor package 160 in accordance with some embodiments. Referring to FIG. 13A, after performing the processes described with respect to FIGS. 1 through 5, the TIM layer 70 with a metal feature 81 embedded within, is placed on the metal layer 50 of the semiconductor package component 22′ and the lid 72 is placed over the TIM layer 70. The lid 72 along with the base layer 79 and the barrier 78 shown in FIG. 13A are same or similar to the corresponding ones described with respect to FIG. 11. The cross-sectional view of the TIM layer 70 and the metal feature 81 in FIG. 13A may be obtained along the reference cross-section A-A′ in a top-down view of the TIM layer 70 and the metal feature 81 in FIG. 13B, wherein like reference numerals refer to like features formed by like processes.

The metal feature 81 may be a sheet and the TIM layer 70 may be formed around the metal feature 81 by plating or the like. The TIM layer 70 shown in FIG. 13A may be formed of same or similar materials as the TIM layer 70 described above with respect to FIG. 6. The metal feature 81 may be formed of same or similar materials as the metal feature 76 described above with respect to FIG. 7A. In some embodiments, the TIM layer 70 has the thickness T1 in a range between about 50 μm and about 100 μm. In some embodiments, the metal feature 81 has a thickness T2 in a range between about 30 μm and about 80 μm, which is smaller than the thickness T1. In some embodiments, a ratio of a volume of the metal feature 81 to the volume of the TIM layer 70 is in a range between about 0.2 and about 0.7, such as about 0.55, which may lead to the complete conversion of the TIM layer 70 to the metal feature 71 in a subsequent step as described in greater details below.

In FIG. 14, after performing the processes similar to the ones described with respect to FIGS. 8A through 9A, such as attaching the lid 72 to the package substrate 66, converting the TIM layer 70 to the metal feature 71 comprising intermetallic compound(s), and forming the conductive connectors 80, the semiconductor package 160 is formed. The metal feature 71 and the metal feature 81 may be collectively referred to as a composite metal feature. In some embodiments, the size of the metal feature 81 may be reduced after the reaction between the metal feature 81 and the TIM layer 70. In some embodiments, the metal feature 71 has straight sidewalls. In some embodiments, after said reaction, a ratio of the volume of the metal feature 81 to the volume of the metal feature 71 is in a range between about 0.2 and about 0.3, such as about 0.25. In some embodiments, the TIM layer 70 is completely converted to intermetallic compound(s) free of particles of a homogenous metallic material. In some embodiments, the TIM layer 70 is partially converted to intermetallic compound(s) with particles of a homogenous metallic material embedded within. The metal feature 71 shown in FIG. 14 may comprise same or similar intermetallic compound(s) described above with respect to FIG. 8B.

For similar reasons described above with respect to FIG. 9A, by converting the TIM layer 70 to the metal feature 71, the risk of forming voids between the semiconductor package components 22′ and the lid 72 during the reflow process of the conductive connectors 80 may be lowered, which may improve the heat transfer efficiency from the semiconductor package components 22′ to the lid 72 during the operation of the semiconductor package 160. The metal feature 81 may also improve the heat transfer efficiency from the semiconductor package components 22′ to the lid 72 during the operation of the semiconductor package 160. As a result, the performance and reliability of the semiconductor package 160 may be improved.

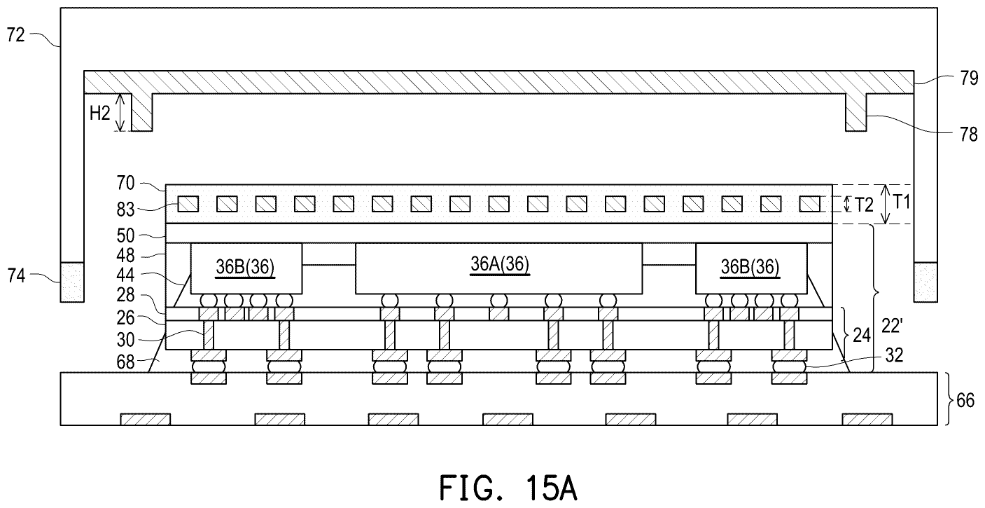

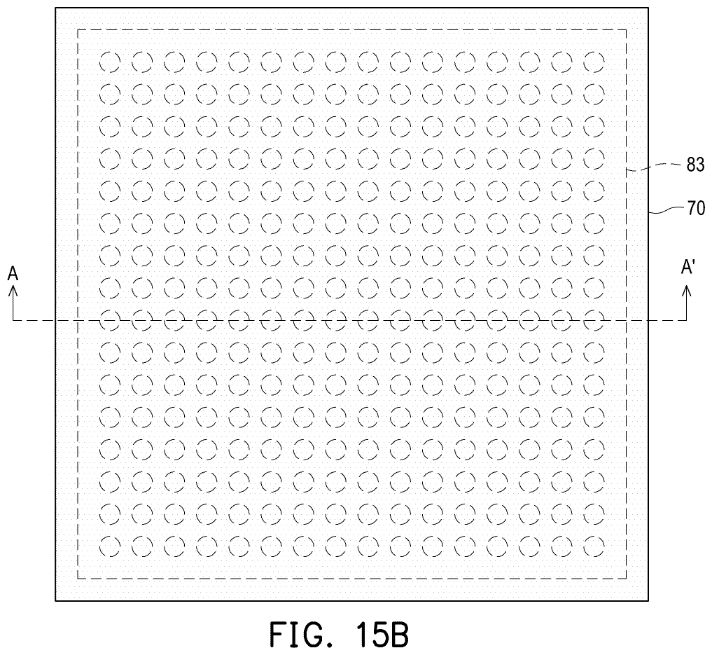

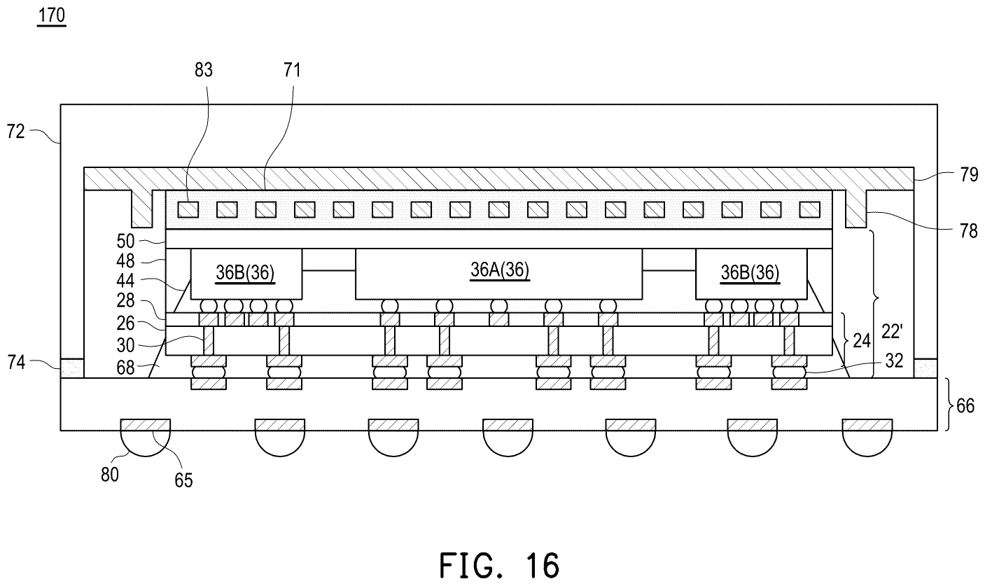

FIGS. 15A, 15B, and 16 illustrate the views of manufacturing steps in the formation of a semiconductor package 170 in accordance with some embodiments. FIGS. 15A and 15B show similar structures to the ones shown in FIGS. 14A and 14B, respectively, in accordance to some embodiments, wherein like reference numerals refer to like features formed by like processes. In the structures shown in FIGS. 15A and 15B, the metal feature 83 may be a sheet with perforations arranged in an array, and the TIM layer 70 may be formed around the metal feature 83 and through the perforations by plating or the like. In FIG. 16, after performing the processes similar to the ones described with respect to FIGS. 8A through 9A, such as attaching the lid 72 to the package substrate 66, converting the TIM layer 70 to the metal feature 71 comprising intermetallic compound(s), and forming the conductive connectors 80, the semiconductor package 170 is formed, which may be similar to the semiconductor package 160 shown in FIG. 14 in accordance to some embodiments, wherein like reference numerals refer to like features formed by like processes.

Various embodiments are described above in the context of a system on chip on wafer on substrate (CoWoS) package configuration. It should be understood that various embodiments may also be adapted to apply to other package configurations, such as integrated chips (SoIC), integrated fan-out on substrate (InFO), or the like.

The embodiments of the present disclosure have some advantageous features. By converting the TIM layer 70 to the metal feature 71 comprising intermetallic compound(s), the risk of forming voids between the semiconductor package components 22′ and the lid 72 during the reflow process of the conductive connectors 80 may be lowered, which may improve the heat transfer efficiency from the semiconductor package components 22′ to the lid 72 during the operation of various semiconductor packages. As a result, the performance and reliability of the various semiconductor packages may be improved.

In an embodiment, a semiconductor package includes a substrate; a semiconductor package component bonded to the substrate, wherein the semiconductor package component includes a semiconductor die; a lid attached to the substrate; and a first composite metal feature between the semiconductor package component and the lid, the first composite metal feature including: a first metal feature, wherein the first metal feature includes a first material, and wherein the first material is an intermetallic compound; and a second metal feature, wherein the second metal feature includes a second material, and wherein the second material is different from the first material. In an embodiment, the intermetallic compound has a melting point higher than 217° C. In an embodiment, the semiconductor package component further includes a first metal layer, wherein the first metal layer is in contact with the semiconductor die and the first composite metal feature. In an embodiment, the first metal feature is in contact with the first metal layer. In an embodiment, the second metal feature is in contact with the lid. In an embodiment, the second metal feature is embedded in the first metal feature. In an embodiment, the first composite metal feature further includes a third metal feature in contact with the lid, wherein the first metal feature is between the second metal feature and the third metal feature. In an embodiment, the first metal feature and the second metal feature contacts each other and have an interdigitating pattern.

In an embodiment, a semiconductor package includes a substrate; a semiconductor package component bonded to the substrate, the semiconductor package component including: a semiconductor die; a molding compound on sidewalls of the semiconductor die; and a first metal layer on surfaces of the semiconductor die and the molding compound; a lid attached to the substrate; and a first composite metal feature between the first metal layer and the lid, the first composite metal feature including: a first metal feature, wherein the first metal feature includes a first material; and a second metal feature, wherein the second metal feature includes a second material different from the first material, wherein first portions of the second metal feature protrude from a second portion of the second metal feature into the first metal feature. In an embodiment, the first material is a first intermetallic compound including indium and copper, a second intermetallic compound including indium and gold, a third intermetallic compound including tin and copper, or a fourth intermetallic compound including tin and gold. In an embodiment, the semiconductor package further includes a barrier on the second portion of the second metal feature, wherein the barrier encircles the first portions of the second metal feature in a top-down view. In an embodiment, the first metal feature has a first volume and the first portions of the second metal feature has a second volume, and wherein a ratio of the second volume to the first volume is in a range between 0.2 and 0.3.

In an embodiment, a method of manufacturing a semiconductor package includes bonding a semiconductor package component to a first side of a substrate, wherein the semiconductor package component includes a semiconductor die and a first metal layer on a surface of the semiconductor die; forming a first metal feature on the first metal layer, wherein the first metal feature includes a first material; and attaching a lid to the first side of the substrate while performing a first heating, wherein a second metal feature is on a bottom surface of the lid, wherein the second metal feature includes a second material different from the first material, wherein the first metal feature and the second metal feature react to generate a third metal feature during the first heating, wherein the third metal feature includes a third material different from the first material and the second material, and wherein the third metal feature extends from the first metal layer to the second metal feature. In an embodiment, the method further includes reflowing electrical connectors on a second side of the substrate while performing a second heating, wherein the third metal feature remains intact during the second heating. In an embodiment, the third material is an intermetallic compound with a melting point higher than 217° C. In an embodiment, the first metal feature melts during the first heating, and wherein first portions of the second metal feature inserts into the first metal feature after the first metal feature melts. In an embodiment, the first portions of the second metal feature are an array of pillars. In an embodiment, the first portions of the second metal feature are concentric rings. In an embodiment, the first portions of the second metal feature are interconnected strips. In an embodiment, the first metal layer includes three sub-layers each including a different metallic material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a substrate;
a semiconductor package component bonded to the substrate, wherein the semiconductor package component comprises a semiconductor die;
a lid attached to the substrate; and
a first composite metal feature between the semiconductor package component and the lid, the first composite metal feature comprising:
a first metal feature, wherein the first metal feature comprises a first material, and wherein the first material is an intermetallic compound; and
a second metal feature, wherein the second metal feature comprises a second material, and wherein the second material is different from the first material, wherein the intermetallic compound has a melting point higher than 217° C., wherein the semiconductor package component further comprises a first metal layer, and wherein the first metal layer is in contact with the semiconductor die and the first composite metal feature.
